(19) United States
(12) Patent Application Publication
(10) Pub. No.: US 2016/0181483 A1
(43) Pub. Date: Jun. 23, 2016

(54) METHOD OF PRODUCING A CONVERTER ELEMENT AND AN OPTOELECTRONIC COMPONENT, CONVERTER ELEMENT AND OPTOELECTRONIC COMPONENT

(71) Applicant: OSRAM OPTO SEMICONDUCTORS GMBH, Regensburg (DE)

(72) Inventors: Boris Eichenberg, Schierling (DE); Herbert Brunner, Sinzing (DE); Simon Jerebic, Tegernheim (DE)

(21) Appl. No.: 14/908,257

(22) PCT Filed: Jul. 30, 2014
(86) PCT No.: PCT/EP2014/066338

§ 371 Date: Jan. 28, 2016

(30) Foreign Application Priority Data
Jul. 30, 2013 (DE) 10 2013 214 896.8

(51) Int. Cl. H01L 33/50

(52) U.S. Cl. CPC H01L 33/505; H01L 2933/0041

(57) ABSTRACT

A method of producing a converter element for an optoelectronic component includes arranging a plurality of converter laminae on a carrier, forming a molded body, wherein the converter laminae are embedded into the molded body, and top sides and undersides of the converter laminae remain at least partly not covered by the molded body; and dividing the molded body to obtain a converter element.

### TECHNICAL FIELD

This disclosure relates to a method of producing a converter element, a method of producing an optoelectronic component, a converter element, and an optoelectronic component.

### BACKGROUND

It is known to equip optoelectronic components, for example, light emitting diode components with converter elements that convert a wavelength of electromagnetic radiation emitted by an optoelectronic semiconductor chip of the optoelectronic component. By way of example, light from the blue spectral range can thereby be converted into light of different color or white light.

Conventional optoelectronic components comprise a plurality of optoelectronic semiconductor chips, for example, a plurality of light emitting diode chips (LED chips). In such optoelectronic components, for the purpose of controlling an optical output power, provision can be made of a possibility of driving the optoelectronic semiconductor chips separately from one another and switching them on or off individually.

It could nonetheless be helpful to provide an improved method of producing a converter element for an optoelectronic component.

### SUMMARY

We provide a method of producing a converter element for an optoelectronic component including arranging a plurality of converter laminae on a carrier, forming a molded body, wherein the converter laminae are embedded into the molded body, and top sides and undersides of the converter laminae remain at least partly not covered by the molded body; and dividing the molded body to obtain a converter element.

We further provide a method of producing an optoelectronic component including producing a converter element according to the method, providing an optoelectronic semiconductor chip; and arranging the converter element above a radiation emission face of the optoelectronic semiconductor chip.

We yet further provide a converter element for an optoelectronic component including a plurality of converter laminae embedded into a common molded body, wherein top sides and undersides of the converter laminae are at least partly not covered by the molded body, and the molded body has a top side elevated above the top sides of the converter laminae.

We still further provide an optoelectronic component including an optoelectronic semiconductor chip having a radiation emission face, and including a converter element arranged above the radiation emission face.

### BRIEF DESCRIPTION OF THE DRAWINGS

FIG. 1 shows a plan view of a carrier with a plurality of converter laminae.

FIG. 2 shows a plan view of a first molded body into which the converter laminae have been embedded.

FIG. 3 shows a sectional side view of the first molded body.

FIG. 4 shows a sectional side view of a first optoelectronic component.

FIG. 5 shows a sectional side view of a second molded body.

FIG. 6 shows a sectional side view of a second optoelectronic component.

### LIST OF REFERENCE SIGNS

100 Carrier
101 Top side
200 Converter lamina
201 Top side
202 Underside
203 Thickness
210 First converter lamina
220 Second converter lamina
230 Third converter lamina
300 First molded body
301 Planar top side
302 Underside
303 Separating region
310 First converter element
400 First optoelectronic component
410 Chip carrier
411 Top side
420 Frame
421 Cavity
430 Potting
500 Optoelectronic semiconductor chip
501 Radiation emission face
502 Underside
510 First optoelectronic semiconductor chip
520 Second optoelectronic semiconductor chip
530 Third optoelectronic semiconductor chip
1300 Second molded body
1301 Convex top side
1310 Second converter element
1400 Second optoelectronic component

### DETAILED DESCRIPTION

Our method of producing a converter element for an optoelectronic component comprises steps of arranging a plurality of converter laminae on a carrier, forming a molded body, wherein the converter laminae are embedded into the molded body, wherein top sides and undersides of the converter laminae remain at least partly not covered by the molded body, and dividing the molded body to obtain a converter element. This method advantageously allows parallel production of a plurality of converter elements in common work operations. Low production costs per converter element can be achieved as a result. In this case, the method advantageously makes it possible to produce converter elements having a variable number of converter laminae. The converter elements obtainable by the method can be used in different optoelectronic components as a result. Since the method makes it possible, in particular, to produce converter elements having more than one converter lamina, the converter elements obtained by the method are suitable for use in optoelectronic components having more than one optoelectronic semiconductor chip. A further advantage of the converter elements obtained by the method is that the individual converter laminae of a converter element are optically separated from one another by the molded body, which can prevent light from radiating across between the individual converter laminae of the converter element.

The converter laminae may be arranged in a regular arrangement on the carrier. Advantageously, the molded body can then be divided into converter elements particularly simply. Moreover, the converter laminae in the converter elements obtained by the method then likewise have a regular arrangement.

The carrier may have receptacle regions that receive the converter laminae at a surface. In this case, the converter laminae are arranged on the top side of the carrier. Afterward, the carrier is set in motion until at least some of the converter laminae, preferably all of them, are arranged in the receptacle regions. The receptacle regions can be formed, for example, as depressions at the top side of the carrier and have a size substantially corresponding to the size of the converter laminae. The carrier can be caused to vibrate, for example, to move the converter laminae into the receptacle regions. The arrangement of the converter laminae at the top side of the carrier is advantageously facilitated as a result. Particularly accurate positioning of the converter laminae is not required during placement of the converter laminae on the top side of the carrier. Rather, the converter laminae move to the positions provided for them in a self-organizing manner.

The molded body may be formed by injection molding, compression molding or transfer molding, preferably by film-assisted transfer molding. The method advantageously permits cost-effective mass production as a result. The use of film-assisted transfer molding advantageously additionally makes it possible particularly easily to leave the top sides and undersides of the converter laminae at least partly not covered by the molded body.

The molded body may be divided by sawing, cutting, stamping or laser separation. Precise division of the molded body is advantageously possible as a result.

The molded body may be divided such that the converter element comprises at least two converter laminae. Advantageously, the converter element obtained by the method can then be used in an optoelectronic component comprising at least two optoelectronic semiconductor chips. In this case, use of the converter element obtained by the method is simpler and more cost-effective than use of a plurality of converter elements each comprising only one converter lamina.

After forming the molded body, a further step may be carried out to change the thickness of at least one converter lamina embedded into the molded body. Advantageously, a color locus of the converter lamina of the converter element obtained by the method can be adapted as a result.

Our method of producing an optoelectronic component comprises steps of producing a converter element according to a method of the type mentioned above, to provide an optoelectronic semiconductor chip, and to arrange the converter element above a radiation emission face of the optoelectronic semiconductor chip. In this case, the optoelectronic semiconductor chip can be, for example, a light emitting diode chip (LED chip). The converter element of the optoelectronic component obtained by the method can convert the wavelength of electromagnetic radiation emitted by the optoelectronic semiconductor chip.

The converter element may be produced such that it comprises a first converter lamina and a second converter lamina. In this case, in addition, a first optoelectronic semiconductor chip and a second optoelectronic semiconductor chip are provided. The converter element is arranged such that the first converter lamina is arranged above a radiation emission face of the first optoelectronic semiconductor chip and the second converter lamina is arranged above a radiation emission face of the second optoelectronic semiconductor chip. This method advantageously makes it possible to produce an optoelectronic component comprising two optoelectronic semiconductor chips. In this case, only one converter element is required jointly for both optoelectronic semiconductor chips. As a result, the method advantageously requires only one work operation to arrange the converter element above the radiation emission faces of the optoelectronic semiconductor chips.

A converter element for an optoelectronic component comprises a plurality of converter laminae embedded into a common molded body. In this case, top sides and undersides of the converter laminae are at least partly not covered by the molded body. Advantageously, this converter element is suitable for use in an optoelectronic component comprising more than one optoelectronic semiconductor chip. In this case, the converter element converts wavelengths of the electromagnetic radiations emitted by a plurality of optoelectronic semiconductor chips. As a result, advantageously, a dedicated converter element is not required for each optoelectronic semiconductor chip.

The converter laminae may comprise wavelength-converting particles.

In this case, the wavelength-converting particles can comprise, for example, an organic phosphor or an inorganic phosphor. The wavelength-converting particles can also comprise quantum dots. The wavelength-converting particles absorb electromagnetic radiation having a first wavelength and emit electromagnetic radiation having a different, typically higher, wavelength.

In the converter element, the molded body may comprise silicone, an epoxy resin, a plastic, a ceramic or a metal. Advantageously, as a result, the molded body is producible simply and cost-effectively and is simple to process. Moreover, the molded body can advantageously have diffuse reflection properties as a result.

The molded body may comprise embedded light-scattering particles, in particular particles comprising TiO₂, ZrO₂, Al₂O₃, AlN or SiO₂. Advantageously, the molded body is optically diffusely reflective as a result.

The molded body may have an underside that terminates substantially flush with the undersides of the converter laminae. Advantageously, the undersides of the molded body and of the converter laminae can then form a planar top side of the converter element if the converter element is used in an optoelectronic component.

The molded body may have a top side elevated above the top sides of the converter laminae. Advantageously, the elevated parts of the molded body of the converter element can serve as an anchor to anchor the converter element to a potting of an optoelectronic component.

A layer of an optically reflective material may be arranged at the top side or the underside of at least one converter lamina. In this case, the layer of the optically reflective material is preferably made so thin that light emerging from the converter lamina can penetrate through the layer substantially without being impeded. Advantageously, the layer can impart an approximately white appearance to the converter lamina of the converter element.

Our optoelectronic component comprises an optoelectronic semiconductor chip having a radiation emission face and a converter element of the type mentioned above arranged above the radiation emission face of the optoelectronic semiconductor chip. Advantageously, the converter element can convert a wavelength of electromagnetic radiation emitted by the optoelectronic semiconductor chip of the optoelectronic component and thereby convert, for example, light from the blue spectral range into white light.

The converter element may comprise a first converter lamina and a second converter lamina. In this case, the optoelectronic component additionally comprises a first optoelectronic semiconductor chip and a second optoelectronic semiconductor chip. The converter element is arranged such that the first converter lamina is arranged above a radiation emission face of the first optoelectronic semiconductor chip and the second converter lamina is arranged above a radiation emission face of the second optoelectronic semiconductor chip. Advantageously, in this optoelectronic component, only one converter element is present, which is provided for both optoelectronic semiconductor chips. Advantageously, the two converter laminae of the converter element are optically separated from one another by the molded body of the converter element that is formed between the converter laminae as a result of which a situation where light from one optoelectronic semiconductor chip radiates across into the converter lamina assigned to the other optoelectronic semiconductor chip is advantageously minimized.

The first optoelectronic semiconductor chip and the second optoelectronic semiconductor chip may be arranged on a surface of a chip carrier. In this case, between the first optoelectronic semiconductor chip and the second optoelectronic semiconductor chip, a potting material is arranged on the surface of the chip carrier. In this case, the potting material can protect the optoelectronic semiconductor chips against damage as a result of external mechanical influences. At the same time, the potting material can advantageously at least contribute to fixing the converter element.

The above-described properties, features and advantages and the way in which they are achieved will become clearer and more clearly understood in association with the following description of the examples explained in greater detail in association with the drawings.

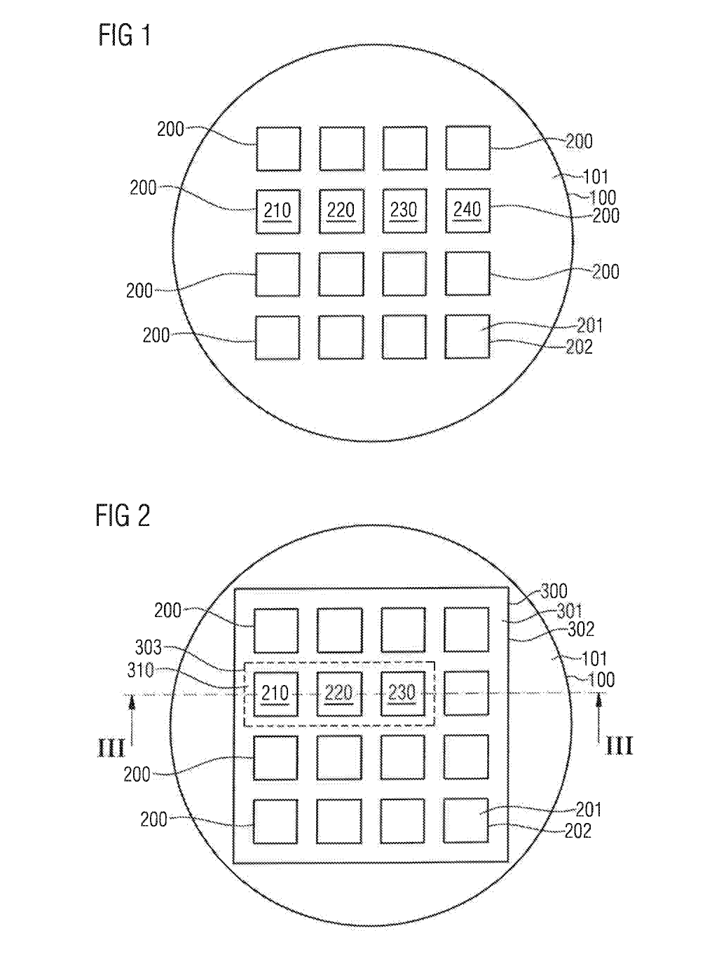

FIG. 1 shows a highly schematic plan view of a top side 101 of a carrier 100 with converter laminae 200 arranged thereon. The carrier 100 can also be designated as a substrate. The carrier 100 can, for example, be formed as a film or comprise a film. The carrier 100 can form a part of a molding tool provided for injection molding, compression molding, transfer molding or some other molding process. The top side 101 of the carrier 100 is preferably formed in a substantially planar fashion. In the example illustrated in FIG. 1, the top side 101 of the carrier 100 has a circular disk shape. However, the carrier 100 and its top side 101 could also have a different geometrical shape, for example, a rectangular shape.

The converter laminae 200 arranged on the top side 101 of the carrier 100 can also be designated as converter layers. Each converter lamina 200 has a top side 201 and an underside 202 opposite the top side 201. In the example illustrated in FIG. 1, the converter laminae 200 are formed in an approximately square fashion. However, the converter laminae 200 could also have a different shape. By way of example, the converter laminae 200 can be formed in a rectangular or circular-disk-shaped fashion.

Each converter lamina 200 converts a wavelength of electromagnetic radiation. For this purpose, the converter laminae 200 can absorb electromagnetic radiation, for example, visible light having a first wavelength and then emit electromagnetic radiation having a different, typically higher, wavelength. By way of example, the converter laminae 200 can convert light having a wavelength from the blue spectral range at least partly into light having a wavelength from the yellow spectral range. A superimposition of an unconverted part of the blue light with the yellow light produced by conversion can then impart a white color impression, for example.

Each converter lamina 200 comprises a matrix material having embedded wavelength-converting particles. The matrix material can comprise glass, silicone or a ceramic, for example. The embedded wavelength-converting particles can comprise an organic phosphor or an inorganic phosphor, for example. The wavelength-converting particles can also comprise quantum dots. The matrix material is preferably optically substantially transparent. The wavelength-converting particles embedded into the matrix material convert a wavelength of electromagnetic radiation.

The converter laminae 200 are arranged in a preferably regular arrangement at the top side 101 of the carrier 100. By way of example, the converter laminae 200 can be arranged in the form of a rectangular lattice having regular rows and columns at the top side 101 of the carrier 100. In this case, the individual converter laminae 200 are spaced apart from one another. The converter laminae 200 are arranged at the top side 101 of the carrier 100 such that the undersides 202 of the converter laminae 200 face the top side 101 of the carrier 100 and are in contact therewith.

The converter laminae 200 may have been arranged, for example, individually successively at their respectively provided positions at the top side 101 of the carrier 100. However, it is also possible to form receptacle regions for the converter laminae 200 at the top side 101 of the carrier 100. By way of example, a depression can be formed at each position provided for a converter lamina 200 at the top side 101 of the carrier 100, the shape and size of the depression approximately corresponding to those of a converter lamina 200. In this case, it is possible to arrange the converter laminae 200 with only low positioning accuracy at the top side 101 of the carrier 100 in a first step. Afterward, the carrier 100 can be set in motion, for example, caused to vibrate such that the converter laminae 200 arranged at the top side 101 of the carrier 100 move independently to the receptacle regions provided for them by virtue of the fact that they slide, for example, into the depressions at the top side 101 of the carrier 100.

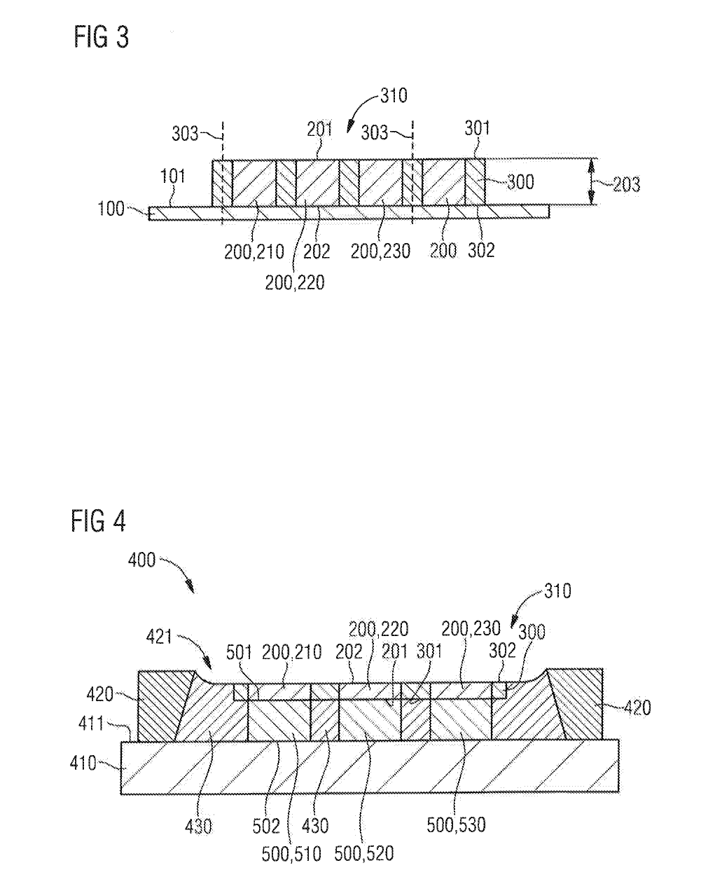

FIG. 2 shows a schematic plan view of the top side 101 of the carrier 100 in a processing state chronologically succeeding the illustration in FIG. 1. A first molded body 300 has been formed at the top side 101 of the carrier 100. In this case, the converter laminae 200 have been embedded into the first molded body 300. FIG. 3 shows a schematic sectional side view of the carrier 100 with the first molded body 300 formed above the top side 101 and with the converter laminae 200 embedded therein.

The converter laminae 200 have been embedded into the first molded body 300 such that the top sides 201 and the undersides 202 of the converter laminae 200 are substantially not covered by the material of the first molded body 300. The first molded body 300 has a planar top side 301 and an underside 302 opposite the planar top side 301. The top sides 201 of the converter laminae 200 terminate substantially flush with the planar top side 301 of the first molded body 300. The undersides 202 of the converter laminae 200 terminate substantially flush with the underside 302 of the first molded body 300. The underside 302 of the first molded body 300 faces the top side 101 of the carrier 100.

The first molded body 300 may have been formed, for example, by injection molding, compression molding, transfer molding or by some other molding process. The first molded body 300 was preferably formed by film-assisted transfer molding. The carrier 100 preferably forms a part of a molding tool used to produce the first molded body 300.

The first molded body 300 can comprise a plastic, a silicone or an epoxy resin, for example. However, the first molded body can also comprise a ceramic or a metal. The first molded body 300 preferably comprises a diffusely reflective material. For this purpose, the material of the first molded body 300 can be filled, for example, with a diffusely reflective filler, for instance with a filler comprising light-scattering particles, in particular particles comprising TiO₂, ZrO₂, Al₂O₃, AlN or SiO₂.

In the plan view in FIG. 2, the first molded body 300 has a rectangular shape. However, it is also possible to form the first molded body 300 with a different shape.

The converter laminae 200 are embedded into the first molded body 300 in a preferably regular arrangement. In this case, the first molded body 300 fills the interspaces between the individual converter laminae 200 and forms an edge extending around the arrangement of the converter laminae 200. As a result, in all the converter laminae 200, all the side faces apart from the top side 201 and the underside 202 are substantially covered by the material of the first molded body 300. The first molded body 300 with the embedded converter laminae 200 forms a mechanically stable arrangement.

The number of converter laminae 200 embedded into the first molded body 300 can be chosen arbitrarily and can be significantly higher than in the exemplary illustration in FIG. 2.

In the processing state of the first molded body 300 with the embedded converter laminae 200 as illustrated in FIGS. 2 and 3, a further processing of the first molded body 300 and/or of the embedded converter laminae 200 can be carried out. By way of example, it is possible, in one or more of the embedded converter laminae 200, to change the thickness 203 dimensioned between the top side 201 and the underside 202 of the respective converter lamina 200. By way of example, the thickness 203 can be reduced in the case of one or more converter laminae 200. This makes it possible to influence a color locus achievable with the respective converter lamina 200.

Proceeding from the processing state illustrated in FIGS. 2 and 3, one or a plurality of functional layers can be applied to the converter laminae 200. Applying additional functional layers to the converter laminae 200 is also possible before or during embedding of the converter laminae 200 into the first molded body 300. Additional functional layers can optionally be applied to the top sides 201 and/or (after the removal of the carrier 100) the undersides 202 of the converter laminae 200. By way of example, a thin layer of a white material can be applied to the top sides 201 or the undersides 202 of the converter laminae 200, the layer concealing a color impression of the converter laminae 200 that arises when the converter laminae 200 are illuminated with ambient light. Preferably, the thin layer of white material is applied to that side 201, 202 of the converter laminae 200 facing away from a surface of an optoelectronic semiconductor chip in an optoelectronic component comprising the respective converter lamina 200. In the following examples, these are the undersides 202 of the converter laminae 200.

The first molded body 300 with the embedded converter laminae 200 can be divided in a subsequent processing step to obtain a plurality of converter elements. The converter elements obtainable by dividing the first molded body 300 can comprise an arbitrary number of converter laminae 200 in an arbitrary arrangement. By way of example, by separation of the first molded body 300 at separating regions 303 depicted schematically in FIGS. 2 and 3, a first converter element 310 is obtained, comprising a first converter lamina 210, a second converter lamina 220 and a third converter lamina 230 of the converter laminae 200 embedded into the first molded body 300. The three converter laminae 210, 220, 230 of the first converter element 310 are arranged in one row in this case. However, converter elements in which converter laminae 200 are arranged in more than one row can also be formed from the first molded body 300.

FIG. 4 shows a schematic sectional side view of a first optoelectronic component 400. The first optoelectronic component 400 can be a light emitting diode component, for example.

The first optoelectronic component 400 comprises a chip carrier 410 having a top side 411. The chip carrier 410 can also be designated as a substrate. The top side 411 of the chip carrier 410 is formed in a substantially planar fashion.

A frame 420 enclosing a cavity 421 is arranged at the top side 411 of the chip carrier 410. The cavity 421 is formed by a region laterally bounded by the frame 420 at the top side 411 of the chip carrier 410. The frame 420 can comprise a plastics material, for example, and may have been formed, for example, by a molding process at the top side 411 of the chip carrier 410.

In the region of the cavity 421, a plurality of optoelectronic semiconductor chips 500 are arranged at the top side 411 of the chip carrier 410 of the first optoelectronic component 400. In the example illustrated in FIG. 4, a first optoelectronic semiconductor chip 510, a second optoelectronic semiconductor chip 520 and a third optoelectronic semiconductor chip 530 are arranged in a series alongside one another in the cavity 421 at the top side 411 of the chip carrier 410. The optoelectronic semiconductor chips 500 can be light emitting diode chips (LED chips), for example.

Each optoelectronic semiconductor chip 500 has a radiation emission face 501 and an underside 502 opposite the radiation emission face 501. The undersides 502 of the optoelectronic semiconductor chips 500 face the top side 411 of the chip carrier 410. The optoelectronic semiconductor chips 500 emit electromagnetic radiation at their radiation emission faces 501. Electrical contacts of the optoelectronic semiconductor chips 500 can be arranged at the undersides 502 of the optoelectronic semiconductor chips 500 and apply electrical voltages to the optoelectronic semiconductor chips 500. The optoelectronic semiconductor chips 500 can be formed as flip-chips, for example.

The first optoelectronic component 400 additionally comprises the first converter element 310 formed from a part of the first molded body 300. The first converter element 310 is arranged above the optoelectronic semiconductor chips 510, 520, 530 of the first optoelectronic component 400 such that the first converter lamina 210 of the first converter element 310 is arranged above the radiation emission face 501 of the first optoelectronic semiconductor chip 510, the second converter lamina 220 of the first converter element 310 is arranged above the radiation emission face 501 of the second optoelectronic semiconductor chip 520, and the third converter lamina 230 of the first converter element 310 is arranged above the radiation emission face 501 of the third optoelectronic semiconductor chip 530. Shape and size of the converter laminae 210, 220, 230 of the first converter element 310 preferably correspond to those of the radiation emission faces 501 of the respectively assigned optoelectronic semiconductor chips 510, 520, 530. However, this is not absolutely necessary.

The first converter element 310 is arranged above the optoelectronic semiconductor chips 510, 520, 530 of the first optoelectronic component 400 such that the top sides 201 of the converter laminae 210, 220, 230 of the first converter element 310 face the radiation emission faces 501 of the optoelectronic semiconductor chips 510, 520, 530 of the first optoelectronic component 400. The converter laminae 210, 220, 230 of the first converter element 310 can be connected to the radiation emission faces 501 of the optoelectronic semiconductor chips 510, 520, 530 by an adhesive bond connection, for example.

A potting material 430 is arranged in a region of the cavity 421 that surrounds the optoelectronic semiconductor chips 510, 520, 530 of the first optoelectronic component 400. The optoelectronic semiconductor chips 510, 520, 530 are embedded into the potting material 430. The potting material 430 preferably extends from the top side 411 of the chip carrier 410 as far as the first converter element 310. Preferably, the cavity 421 is substantially completely filled by the potting material 430.

By the potting material 430, the component parts of the first optoelectronic component 400 are mechanically fixed and protected against damage as a result of external mechanical influences. In addition, the potting material 430 can serve as an optical reflector of the first optoelectronic component 400. In this case, the potting material 430 preferably comprises an optically reflective material. The potting material 430 can comprise silicone, for example, filled with an optically reflective filler.

The converter laminae 210, 220, 230 of the first converter element 310 of the first optoelectronic component 400 convert wavelengths of electromagnetic radiation emitted by the optoelectronic semiconductor chips 510, 520, 530 of the first optoelectronic component 400. The optoelectronic semiconductor chips 510, 520, 530 of the first optoelectronic component 400 can be designed, for example, to emit electromagnetic radiation having a wavelength from the blue spectral range at their radiation emission faces 501. The converter laminae 210, 220, 230 of the first converter element 310 of the first optoelectronic component 400 can convert the electromagnetic radiations emitted by the optoelectronic semiconductor chips 510, 520, 530 into white light. The optoelectronic semiconductor chips 510, 520, 530 of the first optoelectronic component 400 can also be different and emit electromagnetic radiations having different wavelengths. Alternatively or additionally, the converter laminae 210, 220, 230 of the first converter element 310 of the first optoelectronic component 400 could generate light of different light colors.

The first optoelectronic component 400 can be designed such that the optoelectronic semiconductor chips 510, 520, 530 are drivable separately from one another. The sections of the first molded body 300 that are situated between the converter laminae 210, 220, 230 of the first converter element 310 prevent, in the first optoelectronic component 400, electromagnetic radiation emitted by one of the optoelectronic semiconductor chips 510, 520, 530 from passing into one of the converter laminae 210, 220, 230 of the first converter element 310 assigned to a different optoelectronic semiconductor chip 510, 520, 530. The optoelectronic semiconductor chips 510, 520, 530 and the converter laminae 210, 220, 230 assigned to them are thus advantageously optically separated from one another in the first optoelectronic component 400.

The first optoelectronic component 400 can comprise a different number of optoelectronic semiconductor chips 500. The optoelectronic semiconductor chips 500 of the first optoelectronic component 400 can also be arranged in more than one series. In this case, the first converter element 310 of the first optoelectronic component 400 should have a corresponding number of converter laminae 200 in a corresponding arrangement.

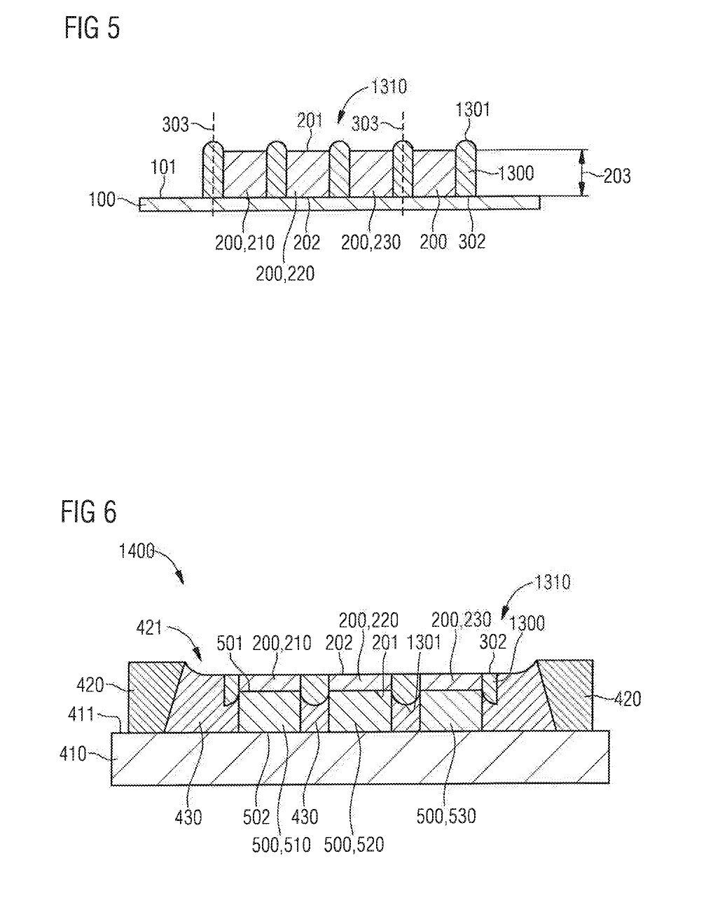

FIG. 5 shows a schematic sectional side view of a second molded body 1300. The second molded body 1300 has correspondences with the first molded body 300 shown in FIGS. 2 and 3. Corresponding components are therefore provided with the same reference signs and will not be described in detail again below. Only the differences between the first molded body 300 and the second molded body 1300 are explained below.

The second molded body 1300 has a plurality of embedded converter laminae 200 and was produced according to a method analogous to production of the first molded body 300. However, the second molded body 1300 has a convex top side 1301 extending in the regions between the individual embedded converter laminae 200 above the top sides 201 of the converter laminae 200. The parts of the convex top side 1301 of the second molded body 1300 that extend above the top sides 201 of the converter laminae 200 can have a rounded, angular, pointed or other cross section.

The second molded body 1300 can be divided to obtain a plurality of converter elements each comprising an arbitrary number of embedded converter laminae 200. By way of example, by dividing the second molded body 1300, it is possible to obtain a second converter element 1310 comprising a first converter lamina 210, a second converter lamina 220 and a third converter lamina 230 arranged in a series alongside one another.

FIG. 6 shows a schematic sectional side view of a second optoelectronic component 1400. The second optoelectronic component 1400 has correspondences with the first optoelectronic component 400 in FIG. 4. Corresponding components are provided with the same reference signs in FIGS. 4 and 6 and will not be described in detail again below. Only the differences between the first optoelectronic component 400 and the second optoelectronic component 1400 are explained below.

The second optoelectronic component 1400 comprises the second converter element 1310 instead of the first converter element 310. The second converter element 1310 is arranged above the optoelectronic semiconductor chips 510, 520, 530 of the second optoelectronic component 1400 such that the convex top side 1301 of the parts of the second molded body 1300 of the second converter element 1310 that extend above the top sides 201 of the converter laminae 200 face the potting material 430 of the second optoelectronic component 1400. The convex sections of the parts of the second molded body 1300 of the second converter element 1310 that extend above the top sides 201 of the converter laminae 200 in this case extend at least partly between the optoelectronic semiconductor chips 510, 520, 530 of the second optoelectronic component 1400. As a result, the convex top side 1301 of the second molded body 1300 of the second converter element 1310 forms an anchoring by which the second converter element 1310 is held particularly reliably by the potting material 430 of the second optoelectronic component 1400. The convex top side 1301 of the second converter element 1310 can also facilitate a positioning of the second converter element 1310 above the radiation emission faces 501 of the optoelectronic semiconductor chips 510, 520, 530 of the second optoelectronic component 1400.

Our methods, components and elements have been illustrated and described in more specific detail on the basis of the preferred examples. Nevertheless, this disclosure is not restricted to the examples disclosed. Rather, other variations can be derived therefrom by those skilled in the art without departing from the scope of protection of the appended claims.

This application claims priority of DE 10 2013 214 896.8, the disclosure of which is hereby incorporated by reference.

1.-15. (canceled)

16. A method of producing a converter element for an optoelectronic component comprising:
arranging a plurality of converter laminae on a carrier,
forming a molded body,
wherein the converter laminae are embedded into the molded body, and
top sides and undersides of the converter laminae remain at least partly not covered by the molded body; and
dividing the molded body to obtain a converter element.

17. The method as claimed in claim 16, wherein the carrier has receptacle regions that receive the converter laminae at a top side,
the converter laminae are arranged on the top side of the carrier, and
the carrier is set in motion until at least some of the converter laminae are arranged in the receptacle regions.

18. The method as claimed in claim 16, wherein the molded body is formed by injection molding, compression molding, transfer molding or film-assisted transfer molding.

19. The method as claimed in claim 16, wherein the molded body is divided such that the converter element comprises at least two converter laminae.

20. The method as claimed in claim 16, further comprising, after forming the molded body, changing the thickness of at least one converter lamina embedded into the molded body.

21. A method of producing an optoelectronic component comprising:
producing a converter element according to the method as claimed in claim 16,
providing an optoelectronic semiconductor chip; and
arranging the converter element above a radiation emission face of the optoelectronic semiconductor chip.

22. The method as claimed in claim 21, wherein the converter element is produced such that it comprises a first converter lamina and a second converter lamina,
a first optoelectronic semiconductor chip and a second optoelectronic semiconductor chip are provided, and
the converter element is arranged such that the first converter lamina is arranged above a radiation emission face of the first optoelectronic semiconductor chip and the second converter lamina is arranged above a radiation emission face of the second optoelectronic semiconductor chip.

23. A converter element for an optoelectronic component comprising a plurality of converter laminae embedded into a common molded body,
wherein top sides and undersides of the converter laminae are at least partly not covered by the molded body, and
the molded body has a top side elevated above the top sides of the converter laminae.

24. The converter element as claimed in claim 23, wherein the converter laminae comprise wavelength-converting particles.

25. The converter element as claimed in claim 23, wherein the molded body comprises embedded light-scattering particles comprising TiO₂, ZrO₂, Al₂O₃, AlN or SiO₂.

26. The converter element as claimed in claim 23, wherein a layer of an optically reflective material is arranged at the top side or the underside of at least one converter lamina.

27. An optoelectronic component comprising an optoelectronic semiconductor chip having a radiation emission face, and comprising a converter element as claimed in claim 23, which is arranged above the radiation emission face.

28. The optoelectronic component as claimed in claim 27, wherein the converter element comprises a first converter lamina and a second converter lamina,
the optoelectronic component comprises a first optoelectronic semiconductor chip and a second optoelectronic semiconductor chip, and
the converter element is arranged such that the first converter lamina is arranged above a radiation emission face of the first optoelectronic semiconductor chip and the second converter lamina is arranged above a radiation emission face of the second optoelectronic semiconductor chip.

29. The optoelectronic component as claimed in claim 28, wherein the first optoelectronic semiconductor chip and the second optoelectronic semiconductor chip are arranged on a surface of a chip carrier, and
between the first optoelectronic semiconductor chip and the second optoelectronic semiconductor chip, a potting material is arranged on the surface of the chip carrier.
